(19) United States
(12) Patent Application Publication
(10) Pub. No.: US 2006/0040459 A1
(43) Pub. Date: Feb. 23, 2006

(54) Method to produce thin film resistor with no resistor head using dry etch

(76) Inventors: Tony Thanh Phan, Flower Mound, TX (US); Daniel Tsai, Plano, TX (US)

Correspondence Address: TEXAS INSTRUMENTS INCORPORATED, P O BOX 655474, M/S 3999, DALLAS, TX, 75265, US

(21) Appl. No.: 10/922,296

(22) Filed: Aug. 19, 2004

(51) Int. Cl. H01L 21/461

(52) U.S. Cl. 438/382; 438/384; 438/720; 438/710

(57) ABSTRACT

A method of fabricating a thin film resistor (100) without a hardmask or resistor head. The resistor material (104), e.g., NiCr, is deposited. The resistor material (104) is patterned and sputter etched to form the resistor body without first depositing a hardmask material. For example, a sputter etch chemistry comprising BCl₃, Cl₂, and Ar may be used to etch the resistor material.

### FIELD OF THE INVENTION

The invention is generally related to the field of forming thin film resistors in semiconductor devices and more specifically to forming a thin film resistor with no resistor head using a dry etch.

### BACKGROUND OF THE INVENTION

Thin film resistors are often used in mixed signal applications such as precision analog-to-digital and digital-to-analog integrated circuits for precision data conversion, which may require precise control of the resistance of the thin film resistor over the operating temperatures and voltages. Other applications include filters and amplifiers. Often the final fine control of the resistance of these precision thin film resistors must be done using laser trimming. A widely used thin film resistor may be formed, for example, from a deposited layer of nickel and chromium alloy and defined using wet chemical etching to remove unwanted thin film resistor material. However, such wet etching techniques may suffer from dimension control problems such as the formation of a jagged etch on the thin film resistor body, resulting in resistor mismatch. FIG. 1 is a top view of a prior art resistor illustrating the jagged edge 10 on the resistor material 12. Because the width of the thin film resistor can substantially affect the resistance of the thin film resistor, such dimension control problems may impair the ability to construct thin film resistors having a precise resistance and may result in yield losses during manufacturing of precision integrated analog circuits incorporating such thin film resistors.

### SUMMARY OF THE INVENTION

The invention is a method for forming a thin film resistor with no resistor head in an integrated circuit. After the resistor material is deposited, it is patterned and etched using a dry sputter etch process without a protective hardmask material thereover.

An advantage of the invention is providing a thin film resistor that does not require a resistor head/hardmask.

This and other advantages will be apparent to those of ordinary skill in the art having reference to the specification in conjunction with the drawings.

### BRIEF DESCRIPTION OF THE DRAWINGS

In the drawings:

FIG. 1 is a top view diagram of a prior art thin film resistor having jagged edges as a result of a wet etch;

FIG. 2 is a three dimensional diagram of the thin film resistor according to an embodiment of the invention;

FIGS. 3A-3B are cross-sectional diagrams of the thin film resistor of FIG. 2 at various stages of fabrication.

### DETAILED DESCRIPTION OF THE EMBODIMENTS

The following description of the preferred embodiments is merely exemplary in nature and is in no way intended to limit the invention or its application or uses. For example, the embodiments of the invention are described in conjunction with a NiCr resistor material in an aluminum metallization process. It will be apparent to those of ordinary skill in the art that the benefits of the invention may be applied to other resistor materials and other metallization schemes, such copper damascene processes. The present invention discloses a process for manufacturing a thin film resistor in an integrated circuit using a dry etch process without a resistor head/hardmask.

A thin film resistor (TFR) 100 formed according to an embodiment of the invention is shown in FIG. 2. TFR 100 is located on a dielectric 102. In a preferred embodiment, dielectric 102 is an interlevel dielectric typically used between metal interconnect levels of an integrated circuit. Metal interconnect levels are formed over a semiconductor body having transistors and/or other devices formed thereon. Alternatively, dielectric 102 may comprise a field oxide region or a shallow trench isolation region. TFR 100 comprises a NiCr layer 104. NiCr layer 104 functions as the thin film resistor body. Other suitable thin film resistor materials are known in the art. For example, tantalum-nitride (TaN) or silicon chromium (SiCr) may alternatively be used. In contrast to the prior art, TFR 100 does not comprise TiW hardmask regions or an Al head layer at the ends of the NiCr layer. Contact is made to TFR 100 from an overlying metal interconnect (not shown) through vias 112 that extend through an overlying dielectric 110.

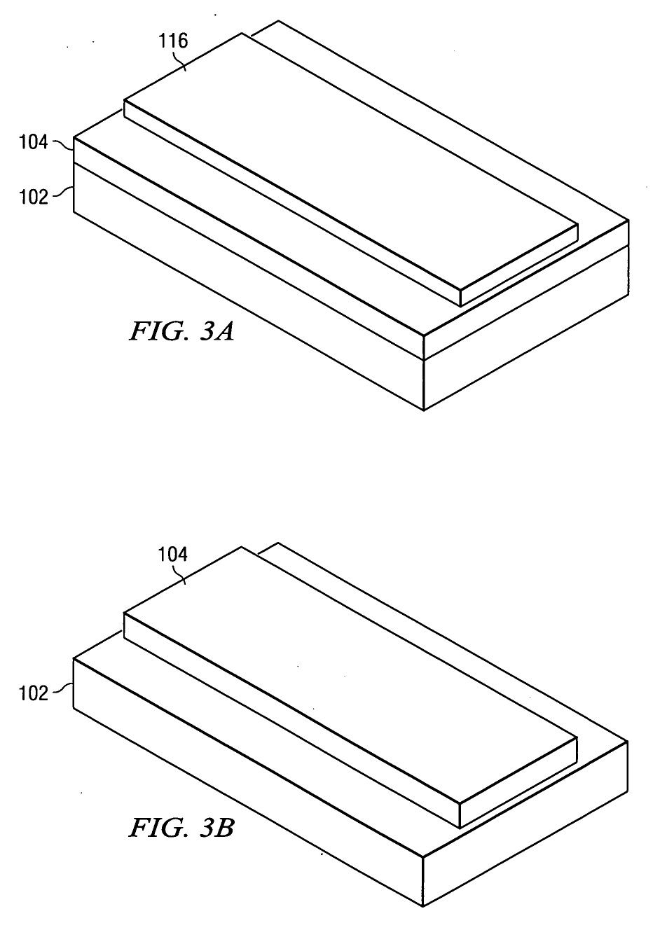

A method for fabricating TFR 100 according to an embodiment of the invention will now be described in conjunction with FIGS. 3A-3B. Referring to FIG. 3A, a layer of resistor material 104 is deposited over the surface of a dielectric layer 102. Preferably, dielectric 102 is an interlevel dielectric suitable for use between metal interconnect levels. Preferably, resistor material 104 comprises an alloy of nickel and chromium (NiCr) and may be, for example, around 10 nm thick. Other suitable resistor materials, such as SiCr, are known in the art. The NiCr/resistor material 104 is annealed. It may be annealed right after deposition using, for example a 410° anneal in air for 30 minutes followed by a 410° anneal in a forming gas for 30 minutes.

Still referring to FIG. 3A, a pattern 116 is formed over NiCr/resistor material 104. Pattern 216 is used to define the location of TFR 100 by masking the area where TFR 100 is desired. Pattern 116 may comprise a photoresist pattern including a bottom anti-reflective coating (BARC) as is known in the art.

With pattern 116 in place, the resistor etch is performed. NiCr/resistor material 104 is dry etched to remove the portions exposed by pattern 116 to form NiCr/resistor body 104. A wet/chemical etch of the prior art causes resist lift-off where the resists lifts-off of the NiCr material during the harsh chemical etch of the NiCr material. Accordingly, a TiW hardmask was used to eliminate the resist lift-off problem. Because the invention uses a dry etch instead of a wet etch, resist lift-off is not a concern and the TiW hardmask can be eliminated.

A sputter etch is utilized to etch the NiCr/resistor layer 104 in contrast to a chemical etch. The sputter etch uses a physical momentum transfer to remove the desired material whereas typical plasma etching relies on a chemical reaction to remove the desired material. An etch chemistry with good sputtering efficiency should be selected. The molecular mass of the etch chemistry is selected to tune the sputter etch efficiency for the resistor material.

A more detailed example of the above sputter etch will now be described. The NiCr resistor material 104 may be removed using a dry etch chemistry of BCl₃/Cl₂/Ar. A preferred embodiment uses about 15 sccm of BCl₃, about 55 sccm of Cl₂, and about 15 sccm of Ar at a power of around 350W (top RF)/250W (bottom RF). The top RF power is selected to control the plasma density and the bottom RF power is selected to determine the sputtering power. The pressure is about 10 mTorr. For cooling, the electrostatic chuck (ESC) temperature may be about 60° C. and helium flow may be used for wafer backside cooling at a pressure of about 10 Torr. Pattern 116 is then removed. The resulting structure is shown in FIG. 3B.

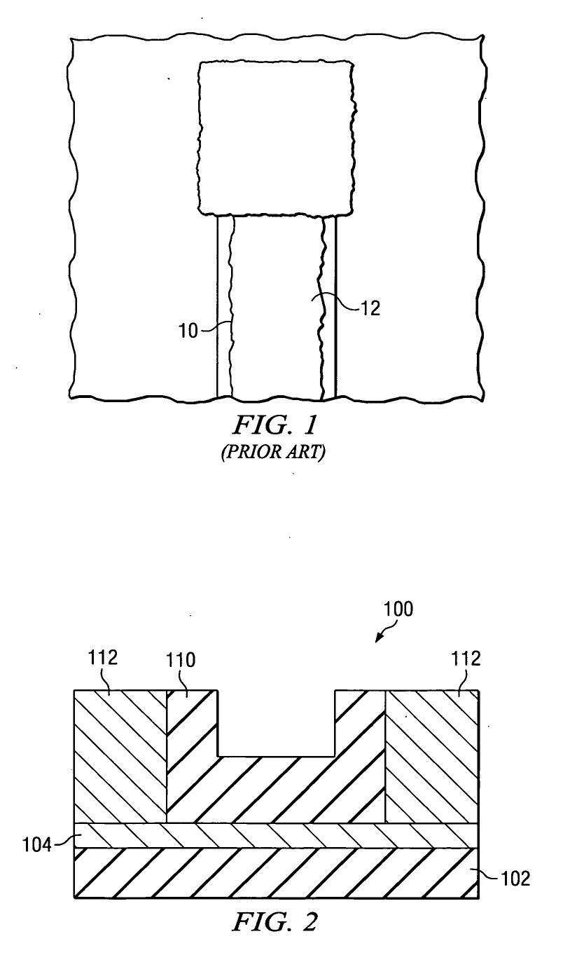

Using a dry etch for the resistor etch is preferable as wet etching tends to result in jagged edges on the resistor material as shown in FIG. 1. A dry etch avoids the resistor mismatch that can occur with wet etching. However, suitable dry etches for NiCr were not previously known. However, the dry sputter etch of the invention provides a uniform, repeatable etch with smooth edges. It should be noted that the sputter etch rate should be controlled to avoid burnt resist caused by the imbalance of heating from sputtering and the cooling of the wafer. Burnt resist affects the shape and quality of the resulting film. Accordingly, the sputter etch rate as controlled by RF powers is balanced with the wafer cooling via, for example, an electrostatic chuck (ESC) with helium flow.

Next, a dielectric 110 is deposited over the structure. Then, vias 112 are etched into dielectric 110 to expose the end portions of resistor body 104. The vias 112 are then filled with conductive material. For example, Ti/TiN/W stack may be used to fill the via. The resulting structure is shown in FIG. 2. Processing then continues to form one or more metal interconnects and package the device.

Table 1 below shows electrical data comparing a standard wet etch approach (Baseline) and a dry etch approach (Dry Etch) with standard TiW hardmask and Al layers to the dry etch approach (DE: NiCr Only) according to an embodiment of the invention without the TiW hardmask and Al layer.

TABLE 1

| | Median | | | Std Dev | | |
|---|---|---|---|---|---|---|
| | | | DE: | | | DE: |
| Parameter | Baseline | Dry Etch | NiCr Only | Baseline | Dry Etch | NiCr Only |
| HEAD_RESISTANCE | 135 | 122 | 246 | 20 | 12 | 41 |
| Via-2 area is smaller than Head area | | | | | | |
| SLOPE_RS | 145 | 150 | 162 | 8 | 3 | 7 |
| NiCr_SHEET_RES_200/50 | 149 | 150 | 148 | 6 | 2 | 2 |
| NiCr_SHEET_RES_12/5 | 181 | 158 | 194 | 13 | 4 | 13 |
| NiCr_SHEET_RES_25/25 | 160 | 158 | 170 | 8 | 3 | 3 |
| NiCr_SHEET_RES_25/12 | 163 | 157 | 165 | 9 | 3 | 4 |
| NiCr_SHEET_RES_25/8 | 164 | 154 | 171 | 10 | 3 | 9 |
| NiCr_SHEET_RES_25/7 | 165 | 153 | 166 | 11 | 3 | 5 |
| NiCr_SHEET_RES_8/5 | 192 | 166 | 223 | 14 | 4 | 16 |
| NiCr_SHEET_RES_7/5 | 195 | 170 | 213 | 15 | 4 | 26 |
| NiCr_SHEET_RES_6/5 | 209 | 180 | 234 | 15 | 4 | 14 |
| NiCr_SHEET_RES_5×100 | 159 | 144 | 142 | 11 | 3 | 5 |
| NiCr_SHEET_RES_2×100 | 175 | 125 | 123 | 29 | 3 | 5 |
| NiCr_BODY_SERPENT_RES_1023/2 | 71579 | 53556 | 51826 | 9928 | 1674 | 2526 |
| NiCr_MATCHING_RES_2×20_.1 | 186 | 129 | 153 | 25 | 3 | 11 |
| NiCr_MATCHING_RES_2×20_.2 | 186 | 129 | 156 | 26 | 3 | 10 |
| NiCr_BODY_COMB_LEAK | 0.0450 | 0.0410 | 0.0640 | 0.0154 | 0.0071 | 0.0134 |
| NiCr_BODY_SERPENT_RES_645/4 | 29 | 25 | 23346 | 2 | 1 | 884 |
| Skipping Al Head dep causing high RES | | | | | | |
| # wafer | 206 | 4 | 2 | 206 | 4 | 2 |

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method of fabricating an integrated circuit, comprising the steps of:
depositing a layer of resistor material;
then, without depositing a hardmask layer, forming a pattern on said layer of resistor material; and
sputtering etching said layer of resistor material to form a thin film resistor body.

2. The method of claim 1, wherein said layer of resistor material comprises NiCr.

3. The method of claim 1, wherein said sputtering etching step using an etch chemistry comprising BCl₃, Cl₂, and Ar.

4. The method of claim 1, further comprising the steps of:
removing said pattern;
forming a dielectric layer over said resistor body;
etching a via in said dielectric layer;
filling said via with a conductive material; and
forming a metal interconnect in contact with said via.

5. The method of claim 1, wherein said pattern comprises resist and a bottom anti-reflective coating.

6. A method of fabricating an integrated circuit, comprising the steps of:
providing a semiconductor body having a first dielectric layer formed thereover;
depositing a layer of resistor material over said first dielectric layer;
then, without depositing a hardmask layer, forming a resistor pattern on said layer of resistor material; and
sputter etching said layer of resistor material to form a resistor body.

7. The method of claim 6, wherein said sputter etching of the resistor material step uses an etch chemistry comprising BCl₃, Cl₂, and Ar.

8. The method of claim 6, wherein said resistor material comprises NiCr.

9. The method of claim 6, wherein said resistor pattern comprises resist and a bottom anti-reflective coating.

10. A method for fabricating a thin film resistor on a semiconductor body, comprising the steps of:
depositing an alloy of nickel and chromium over a first dielectric layer; and
then, without depositing a hardmask layer, sputter etching to remove a portion of said alloy to form a resistor body, wherein sputter etching uses an etch chemistry comprising BCl₃, Cl₂, and Ar.

11. The method of claim 10, further comprising the steps of:
depositing a second dielectric layer over said resistor body;
etching a via through said second dielectric layer to expose an end portion of said resistor body; and
filling said via with a conductive material.

12. The method of claim 10, wherein said sputter etching step comprising the steps of:
flowing BCl₃ at a flow rate of about 15 sccm;
flowing Cl₂ at a flow rate of about 55 sccm; and
flowing Ar at a flow rate of about 15 sccm.
